(19) United States
(12) Patent Application Publication
(10) Pub. No.: US 2002/0036347 A1
(43) Pub. Date: Mar. 28, 2002

(54) LOCAL INTERCONNECT STRUCTURES AND METHODS

(76) Inventor: THEODORE W HOUSTON, RICHARDSON, TX (US)

Correspondence Address: TEXAS INSTRUMENTS INCORPORATED, P O BOX 655474, M/S 3999, DALLAS, TX, 75265

(21) Appl. No.: 09/428,835

(22) Filed: Oct. 28, 1999

Related U.S. Application Data
(60) Provisional application No. 60/105,962, filed on Oct. 28, 1998.

(51) Int. Cl. H01L 29/40; H01L 23/52; H01L 23/48

(52) U.S. Cl. 257/758

(57) ABSTRACT

An integrated circuit comprising a field effect transistor gate self aligned to its respective moat in conjunction with a local interconnect structure. The spacing between two adjacent transistors with collinear gate alignments is minimized.

### BACKGROUND AND SUMMARY OF THE INVENTION

The present invention relates to integrated circuit structures and fabrication methods, especially to the use of local interconnects in silicon-based circuit processing.

### BACKGROUND: INTERCONNECTS

Interconnects are used to electrically connect isolated devices in an integrated circuit. They may generally be classified as either local interconnects or global interconnects depending on their structure. For the purposes of the presently disclosed teachings, interconnects will be discussed with reference to their application in electrically connecting the gates and moat regions of MOSFET devices formed on a silicon semiconductor substrate.

Interconnects are a necessary part of every integrated circuit chip. Transistors, inductors, and capacitors need to be wired together to create circuits. This is accomplished by means of interconnects. FIG. 13 illustrates a conventional transistor and interconnect structure. (It should be noted that this particular example uses LOCOS field oxide which is not commonly used in modern processes.) This MOS structure has a dielectric layer 1360 (PMD) between the polysilicon gate/interconnect level 1355 and the first layer of metalization (Metal 1) 1310. There are also dielectric layers between metal levels called intermetal dielectrics 1330 which are used to isolate metalization layers from other metallization layers. In the example depicted in FIG. 13, there are two metalization layers and the intermetal dielectric 1330 separates Metal 1 1310 from the second layer of metalization (Metal 2) 1320. Contact is made between Metal 1 1310 and the polysilicon 1350 where openings 1370 have been etched into the PMD 1360. These openings in the PMD 1360 are referred to as contact holes 1370. Openings in the intermetal dielectric layers 1330, known as vias 1370, are used to make contact between Metal 1 1310 and Metal 2 1320.

### Background: Split-polysilicon Gate Formation

In the prior art, the split-poly process started with a gate oxide. Then polysilicon is deposited and the moat is patterned. Next, a LOCOS isolation region was grown and a second polysilicon layer is deposited and the gate is patterned. This self-aligns the edge of the polysilicon that is at the corner of the isolation region, but the gate still extended over the field.

Innovative Structures and Methods

The present application describes a new kind of transistor and isolation structure, in which the transistor gate and local interconnect functions are allocated between two different thin film layers. The transistor gates are formed by one patterned conductive layer which only overlies the active areas, and does not run over the isolation areas. Preferably (but not necessarily) the top of this patterned layer is coplanar with the top of the isolation areas. Another patterned conductive layer runs over the isolation areas and over the one patterned layer, and makes distributed contact to the one patterned layer. Thus this second layer provides a local interconnect which electrically connects the transistor gates (of the first layer) in whatever electrical configuration is desired.

Advantages of the disclosed methods and structures include increased flexibility in routing local interconnects as well as increased device packing densities on chips.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows a cross section of a partially fabricated MOSFET with a local interconnect in which isolation regions were formed using a modified shallow trench isolation process.

FIGS. 2A-E show sequential steps in the formation of a transistor using a modified shallow trench isolation process.

FIG. 3 shows an example of prior art in which the spacing between two adjacent transistors with collinear gate alignments is minimized.

FIG. 4 shows the presently preferred embodiment wherein the spacing between two adjacent transistors with collinear gate alignments is minimized.

FIG. 5 shows an alternative embodiment with the local interconnect of a transistor underlapping both ends of the gate.

FIGS. 6A-B show an alternative embodiment wherein a contact via is opened directly over the transistor gate.

FIG. 6C shows an alternative embodiment with a local interconnect underlapping both ends of the gate and a contact formed to the local interconnect directly over the gate.

FIGS. 7A-B show a layout and sectional view of a portion of an SRAM memory cell with word-line interconnects not centered over gates.

FIG. 8 shows the layout of two adjacent transistors in a conventional decoder integrated circuit (prior art).

FIGS. 9A-B show a layout and sectional view of an alternate embodiment wherein two adjacent transistors in a decoder integrated circuit have interconnects with contacts directly over transistor gates.

FIGS. 10A-C show steps in a process for forming an alternative embodiment where a contact is formed to the moat of a transistor which is self-aligned to the edge of the moat.

FIGS. 11A-E show sequential steps in the fabrication of a transistor gate which extends selectively into the isolation region.

FIGS. 12A-H show sequential steps in a split-polysilicon fabrication process.

FIG. 13 shows a transistor with metal-1 global interconnect layer.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

Definitions:

Following are some of the technical terms which are used in the present application. Additional definitions can be found in the standard technical dictionaries.

Amorphous: A material in which there are no crystalline portions.

Back-Bias or Body-Bias: Back-bias is the voltage applied to the semiconductor material under the gate of the FET.

Bandgap: The range of energies which is normally unavailable to carriers in an undoped semiconductor. For example, the bandgap of germanium is about two-thirds of a Volt, that of silicon is slightly more than a Volt, and that of gallium arsenide is slightly less than 1½ Volts.

Body: The material within which a transistor channel is formed.

Body Effect: A shift in the threshold voltage of a transistor due to capacitive coupling between the gate voltage and the body.

Carrier: In a semiconductor, an electron or hole, which can move around in the semiconductor material to transport charge. The movement of carriers is how electrical current flows.

CMOS: A circuit containing at least one NMOS and at least one PMOS transistor, or a chip containing at least one such circuit.

Contact: An approximately vertical connection from metallization to a semiconductor layer (whether a gate line or a source/drain diffusion), possibly including a barrier layer to separate the metal from the semiconductor.

Contact Resistance: The resistance of a contact, or more generally the inverse of the conductance per unit area of a given contact interface. Units are ohms times area.

Depletion: Reduction of carrier density, in a volume of semiconductor material, due to applied voltage.

Diffusion: The process of diffusion is the spontaneous movement of dopant or impurity atoms through a semiconductor, at a rate which depends on temperature and on the particular elements involved. The noun “diffusion” usually refers to a doped portion of a semiconductor material.

Diffusion Barrier: A material in which impurities have a low diffusion constant. For example, titanium nitride is often used as a conductive diffusion barrier material in silicon integrated circuit technology.

Dopant: An atom added to a semiconductor, which, when activated, provides a “carrier” (i.e. an electron or hole) which can move around in the semiconductor to enable the flow of current. For example, in silicon technology, boron or gallium can act as P-type dopants (or “acceptors”), and phosphorus, arsenic, or antimony can act as N-type dopants (or “donors”).

Drain: In a field-effect transistor, the diffusion to which majority carriers are emitted. For example, in an NMOS transistor, the drain will often be found connected to the more negative supply voltage (e.g. ground). In a PMOS transistor, the source will often be found connected to a positive power supply voltage.

Electromigration is the physical transport of material within a conductor which occurs at high current densities. In integrated circuit metallization this transport can cause a conductor to neck down and fail in service.

Field-Effect Transistor (FET): A three-terminal device in which current between two current-carrying electrodes (“Source” and “drain”) is controlled by the voltage applied to a “gate” terminal. volatile memory (e.g. DRAM or SRAM) is a memory in which data will be lost when power is momentarily removed from the system.

Gate: In a field-effect transistor, the electrode to which a control voltage is applied to modulate the conduction of the transistor.

MOSFET: An insulated-gate field effect transistor, in which the gate is separated from the channel by a thin layer of an insulating material.

N-channel: A channel of n-type semiconductor material induced in a FET as a result of a bias applied to the gate. This channel allows current to flow from the drain to the source of an NMOS transistor. Typically an N-type channel is formed by surface inversion of p-type material, but it may also be formed by surface enhancement of n-type material.

NMOS: An n-channel field effect transistor, or a circuit or chip containing this type of transistor.

N-type: A volume of semiconductor which normally includes an excess of electrons. This can be achieved by introduction of “donor” dopants (such as phosphorus, arsenic, or antimony in silicon).

P-channel: A channel of p-type semiconductor material induced in a FET as a result of a bias applied to the gate. This channel allows carriers to flow from the source to the drain of a PMOS transistor.

P-type: A volume of semiconductor which normally includes an excess of holes. This can be achieved by introduction of “acceptor” dopants (such as boron or gallium in silicon).

PMD (pre-metal dielectric)—a dielectric layer between the polysilicon gate/interconnect level and the lowest metal layer (which is conventionally referred to as “Metal 1”). (Sometimes the term “multilevel oxide”, or “MLO,” is used instead of PMD.) The dielectric layers between metal levels are called intermetal dielectrics. (Sometimes the term “interlevel dielectric,” or “ILD”, is used instead.) The intermetal dielectric between Metal 1 and Metal 2 is designated as DM1, etc. Contact holes are openings in the PMD. Openings in the intermetal dielectric are called vias—these allow contact to be made between Metal 1 and Metal 2, Metal 2 and Metal 3, etc.

PMOS: A p-channel field effect transistor, or a circuit or chip containing this type of transistor.

POLY: Originally engineering slang for polysilicon, this term (or the related terms POLY1, POLY2, POLY3, POLY4) also refers to a patterned conductor level which provides transistor gates, resistors, or sometimes TFT transistor channels.

Polycide: A composite of polycrystalline silicon and a metal silicide.

Polycrystalline: A material which is neither monocrystalline nor amorphous, but instead includes monocrystalline grains separated by grain boundaries.

Polysilicon: Polycrystalline silicon.

Semiconductor: A material which is less conductive than a metallic material, but more conductive than an insulator. (More precisely, a semiconductor will have a nonzero “bandgap” between its valence and conduction bands, which is no more than a few electron volts at the very most.) The most frequently used semiconductor material is silicon, but there are many others, including gallium arsenide (or “GaAs”), silicon-germanium, mercury cadmium telluride, indium phosphide, gallium-indium arsenide-phosphide, and silicon carbide.

Source: In a field-effect transistor, the diffusion from which majority carriers are emitted. For example, in an NMOS transistor, the source will often be found connected to the more negative supply voltage (e.g. ground). In a PMOS transistor, the source will often be found connected to a positive power supply voltage.

TFT: A thin film transistor, in which the channel is made of a polycrystalline (rather than monocrystalline) material.

Threshold Voltage: The voltage at which a transistor starts to turn on.

Via: An approximately vertical connection from one metallization layer to another.

Gate Self-aligned to Moat Edge

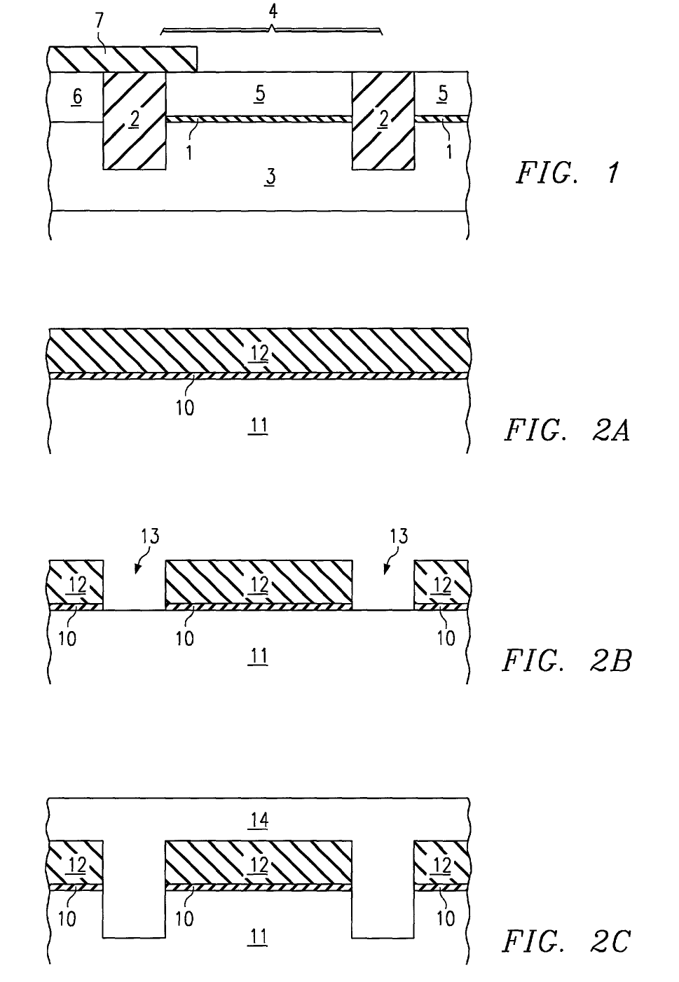

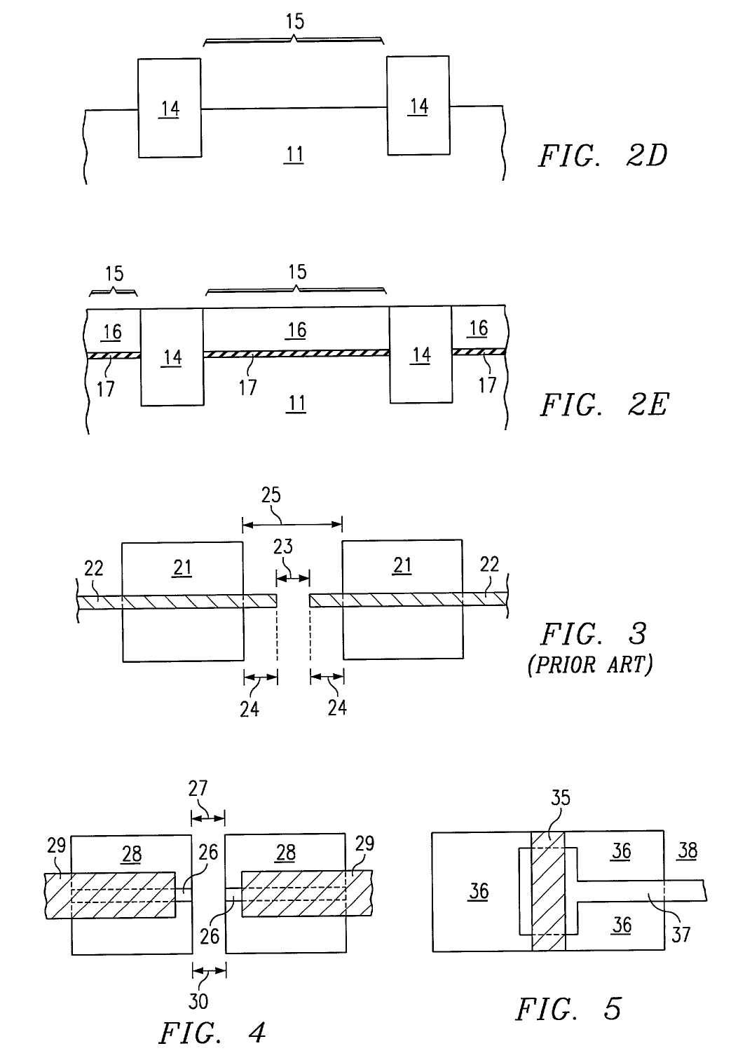

The present teachings disclose the self-alignment of field effect transistor gates to their respective moats in conjunction with the use of local interconnect structures. A cross section of a sample embodiment of the invention is shown in FIG. 1. Device isolation regions 2 have been patterned to define moat regions 4 in a silicon substrate 3. The field oxide 2 composing the isolation regions 2 does not exhibit the characteristic bird's beak infringement into the moat produced by a LOCOS isolation process; the present invention employs a variant of the shallow trench isolation process which produces substantially planar lateral surfaces on the field oxide. The method used to pattern the isolation regions and transistor gate will now be discussed with reference to FIGS. 2A-E, which illustrate a cross-section of the wafer at various stages in the disclosed process.

In FIG. 2A, a layer of silicon oxide 10 (typically 5-20 nm thick) is thermally grown on the surface of a silicon wafer to function as a pad oxide 12. A layer of silicon nitride 12 (typically, 100-200 nm thick) is then deposited by chemical vapor deposition to serve as an oxidation mask, and an overlying layer of photoresist is deposited and patterned to mask active regions on the substrate. Unmasked regions of nitride and underlying oxide are subsequently dry-etched to expose portions of the underlying substrate. A shallow trench is etched into the exposed substrate where isolation regions 13 will be formed as seen in FIG. 2B.

A channel-stop implant is then performed to introduce dopants into the unmasked substrate where isolation regions will be formed. In FIG. 2C, the combination of a thermal oxidation process and an oxide deposition process has been performed to form a field oxide 14 filling the trench and overlaying the masking nitride layer 12. A chemical-mechanical polishing step is performed to both planarize the surface of the wafer and to remove the oxide layer 14 over the silicon nitride 12, after which the remaining silicon nitride 12 and underlying pad oxide 10 are removed in a wet-chemical etch process.

The resulting isolation region structure is illustrated in FIG. 2D. The upper surface of the field oxide 14 is everywhere 1000 Angstroms above the surface of the substrate 11, and extends into the substrate to a depth of approximately to 1000 Angstroms although it could be shallower or deeper depending on the process parameters. Active devices will be formed in the moat region 15, which is laterally surrounded by the field oxide 14.

In the presently preferred embodiment, upper surfaces of transistor gates 16 will be coplanar with the upper surfaces of surrounding field oxides 14, and gates 16 will nowhere overlie isolation regions 14, as is illustrated in FIG. 2E. To this end, a damascene gate fabrication process may be used. The initial nitride over the moat is retained, whereafter a trench is etched in the nitride to expose the underlying substrate where the gate is to be formed. A gate oxide 17 is then thermally grown by wet oxidation, and a subsequent layer of polysilicon gate material or other gate material is deposited. Finally, a chemical-mechanical planarization is performed to form a gate 16 lying entirely within the etched trench which is self-aligned to the moat edges. This method is advantageous because there is no possibility of a residual gate filament along the moat edge.

Alternatively, a replacement-gate variation of the above damascene gate fabrication process can be used. The layer of nitride covering the moat is first patterned to leave a strip where the gate will be formed. Following this, a source/drain implant is performed, the moat is filled by a subsequent oxide deposit, and a chemical-mechanical planarization is performed. Finally, the strip of nitride is removed to expose the underlying substrate where the gate is to be formed, and the above damascene process is performed to complete the gate fabrication. Note that etch-back can be used in plane of chemical mechanical polishing (CMP) for planarization.

In an alternative embodiment, instead of a damascene gate fabrication process, the following process can be used. First form a shallow trench isolation (STI), then remove the nitride. Next, form the gate oxide and deposit the gate. Following this step, planarize to STI and pattern the gate.

Local Interconnect Formation

As illustrated in FIG. 1, the present teachings disclose a method of depositing a patterned, thin-film conductive layer which overlies and makes contact with transistor gates 5 to function as a local interconnect 7. Prior to depositing this local interconnect layer, a dielectric layer 6 is deposited and planarized such that it completely overlies transistor moat regions 4 but leaves the upper surfaces of gates 5 exposed. The subsequently deposited conductive local interconnect layer 7 will contact gates 5 wherever it overlies them. Contacts to moat may be formed by etching openings in the dielectric layer overlying the moat prior to depositing the local interconnect layer.

An alternative embodiment teaches the deposition of a conductive local interconnect layer prior to the deposition of a dielectric layer over transistor moats. The local interconnect layer will contact any moat or gate it crosses. This might require a widening of transistor gates at points of contact, depending on gate sidewall thicknesses and desired local interconnect alignments.

In an alternative embodiment, instead of filling the area over the moat with dielectric, form a dielectric sidewall on the gate and fill the remaining area with a conductor planarized to the gate sidewall.

Local Interconnect Alignment

FIG. 3 depicts prior art in which two transistors with moat regions 21 and gates 22 are separated by a device isolation region 25. Because the gates 22 overlap the isolation region 25 by gate overlap margin 24, the minimum transistor spacing is given by the sum of the minimum allowable distance between gates 23 and the gate overlap margins 24.

The present teachings disclose the formation of local interconnects that are not required to overlie the entire gate; nor are they required to overlap the ends of gates to extend over isolation regions.

FIG. 4 illustrates the presently preferred embodiment, in which two adjacent transistors have been formed in active regions 28 and are separated by an isolation region 27 patterned using the aforementioned modified surface trench isolation process. Gates 26 are self-aligned to the edges of moats 28 and are overlain by and make contact to local interconnects 29. Local interconnects 29 nowhere overlie isolation region 27; in the present example they underlap the ends of the gates 26, but they could also be aligned with the ends of the gates 26 without necessitating an increase in transistor spacing 30. Minimum transistor spacing 30 in this embodiment is limited to the minimum required distance between the moats 28 of adjacent devices. Because this minimum moat spacing 30 is less than the minimum gate spacing 23 and gate overlap 24 of prior art as depicted in FIG. 3, the present embodiment enables a reduction in isolation region width. By reducing the isolation region width between active devices on a chip, higher packing densities can be achieved.

Alternative Embodiment—Zero Overlap at Both Edges

In the alternative embodiment illustrated in FIG. 5, a transistor formed using the aforementioned modified shallow trench isolation process is comprised of a polysilicon gate 35 self-aligned with an active region 36. A conductive local interconnect layer 37 is deposited and patterned to overlie the gate 35, but underlaps the gate 35 at both ends. Electrical contact with other devices in the integrated circuit is made by patterning the local interconnect 37 to extend over the isolation region 38 perpendicular to the gate 35.

Alternative Embodiment—Contact Over Gate

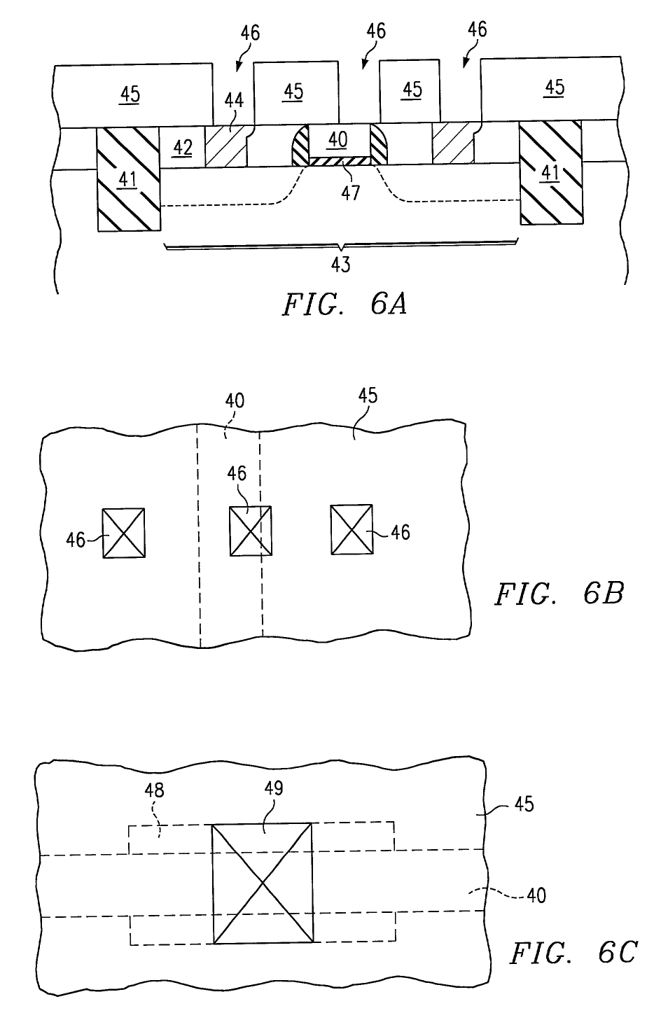

In the alternative embodiment illustrated in FIGS. 6A-B, a dielectric layer is deposited over both moat and gate regions prior to deposition of the interconnect layer. The subsequently formed interconnect level will be global instead of local, requiring contact openings to both gates and moats. A sample fabrication process for this embodiment is as follows:

First, isolation regions 41 are formed in the substrate using the aforementioned shallow trench isolation process. This is followed by the growth of a gate oxide 47 and the deposition of gates 40 which are self-aligned with their respective moats 43. A dielectric layer 42 is then deposited and planarized over moats 43, in which contact openings are etched and contacts 44 are formed. This is followed by a blanket deposition of dielectric material 45 over gates 40, contacts to moats 44, and isolation regions 41. Contact vias 46 to underlying gates 40 and moat contacts 44 are then opened in the overlying dielectric material 45, where electrical connections can be made with the subsequently deposited global interconnect layer.

Alternatively, prior to the above blanket deposition of dielectric material 45 over gates 40, a thin layer of conductive local interconnect material 48 can be deposited and patterned over gates. Optionally, the local interconnect nowhere overlies isolation regions 41, as shown in FIG. 6C. A blanket deposition of dielectric material 45 can then be made, and gate contact vias 49 can be etched directly over the local interconnect 48. Optionally, the local interconnect 48 can make contact to multiple gates and/or moat contacts. In prior art, gate contacts to overlying global interconnect levels are formed by opening a via to the gate where it extends into an isolation region. In the presently disclosed embodiment, the gate does not extend into isolation regions and contact vias may be opened directly over the gate. This allows minimum geometry to be used for lateral isolation regions on every side of the active device.

This embodiment is particularly useful in the design of decoder or Domino integrated circuit layouts. FIG. 8 illustrates prior art in which two adjacent transistors, each comprised of a polysilicon gate 64 capacitively coupled to an active region 63, are overlain by and make contact to a metal interconnect layer 62 at contact points 65. Where poly gates 64 overlap isolation regions 68, contact vias are etched in the overlying dielectric if contacts 65 with the overlying metal layer are desired. Minimum transistor spacing in this example of prior art is generally the sum of the minimum required gate spacing 66 and the minimum gate overlap margins 67.

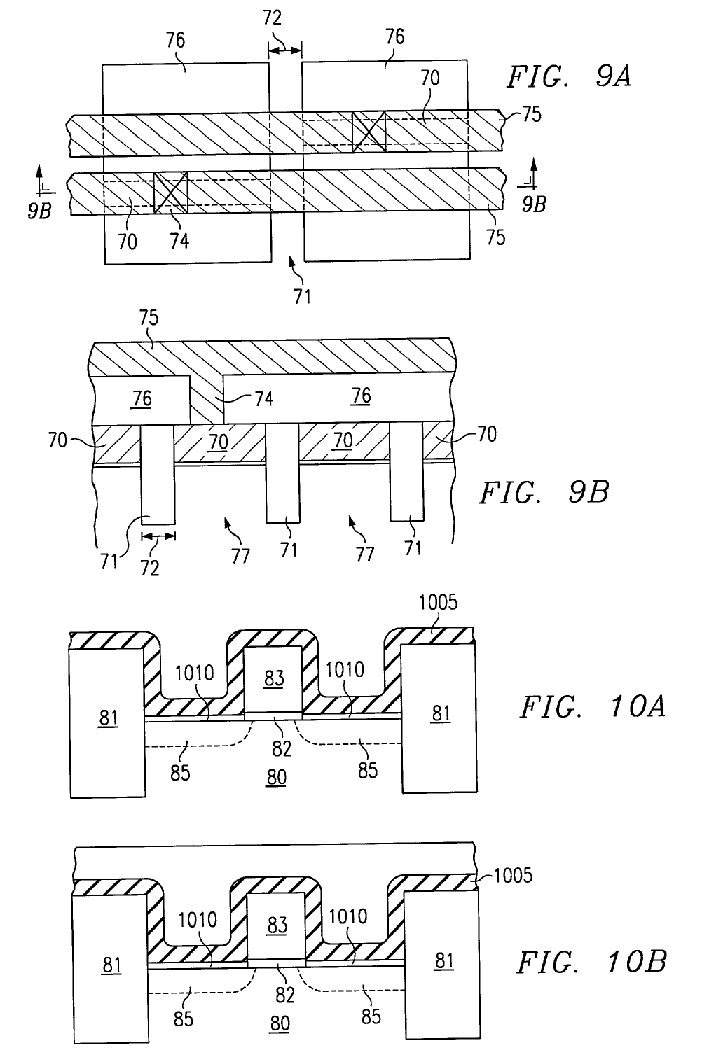

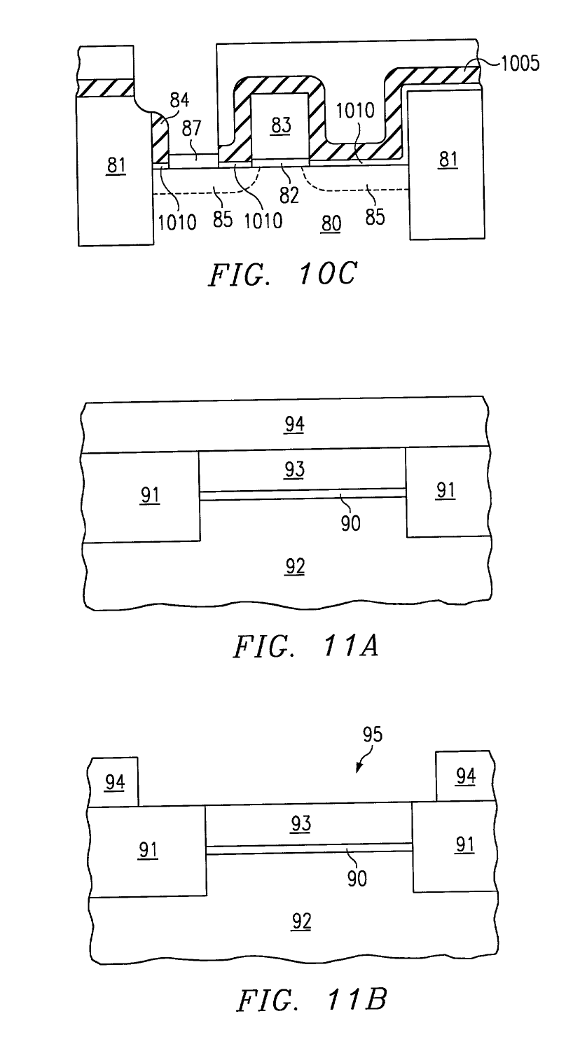

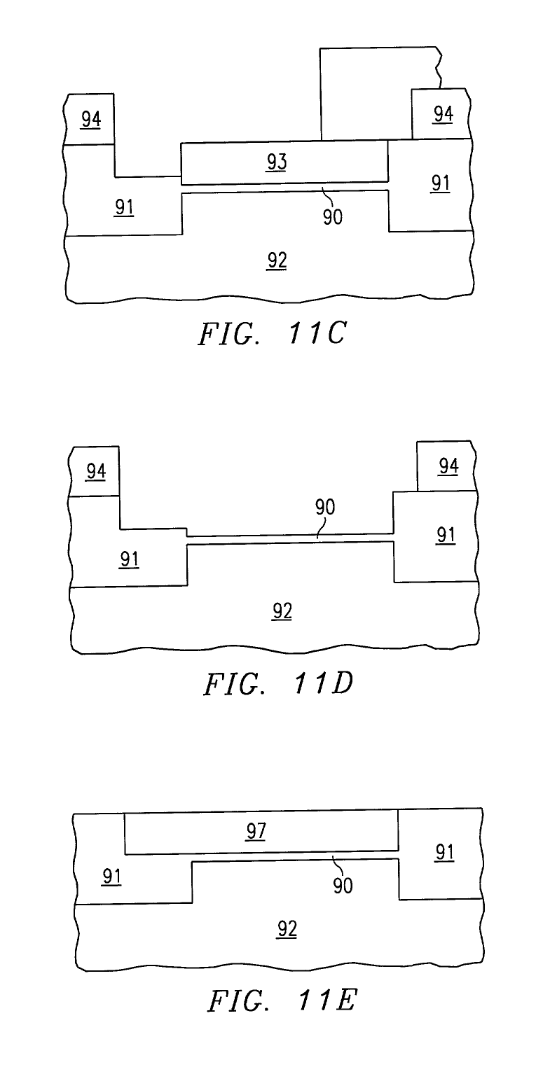

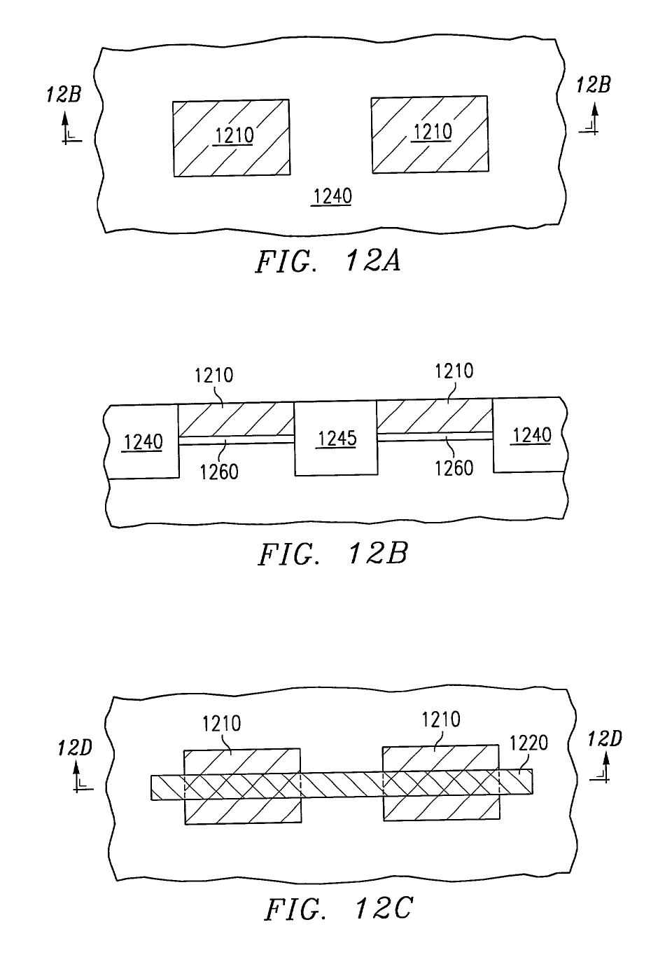

As illustrated in FIGS. 9A-B, the presently disclosed process allows for the fabrication of transistors with gates 70 that do not overlie isolation regions 71. By opening contact vias 74 in the overlying dielectric layer 76 directly over transistor gates, isolation region 71 widths can be minimized. Minimum transistor spacing in the present embodiment will be equivalent to the minimum required spacing between active regions 72.

Alternative Embodiment—Gate With Off-centered Local Interconnect

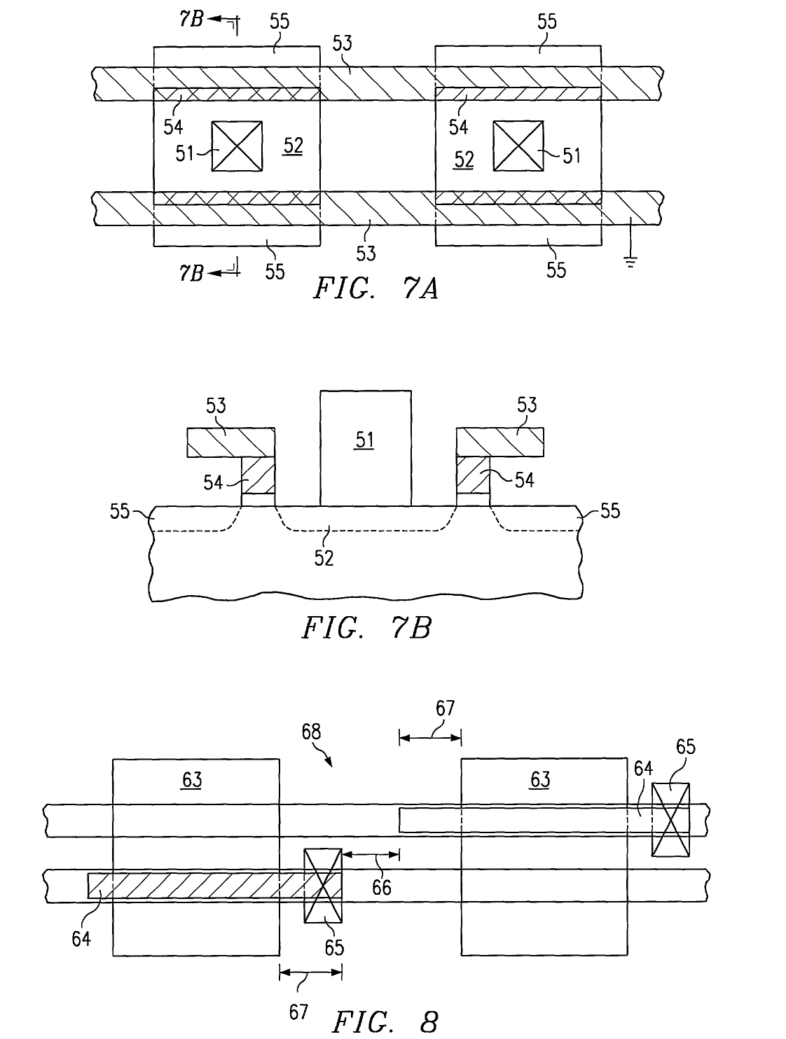

FIG. 7 illustrates an alternative embodiment wherein local interconnects 53 are not centered over their respective polysilicon gates 54. This method is disclosed in the context of an SRAM cell layout, but can of course be practiced in the fabrication of other integrated circuits.

In the embodiment illustrated by FIGS. 7A-B, the word-line interconnects 53 of an SRAM cell are not centered over underlying gates. The lateral edges of the word-line interconnects closest to bit-line contacts 51 are aligned with the lateral edges of underlying gates 54 which are closest to bit-line contacts 51. This results in an L-shaped gate-interconnect structure (FIG. 7B, 53 and 54) instead of the T-shaped structure produced by prior art processes. This method of alignment allows for a minimum spacing arrangement between poly gates 54 and the bit-line contact structure 52, which allows for an increase in device packing density on the chip.

Alternative Embodiment—Contacts Self-Aligned to Moat

FIG. 10 illustrates an alternative embodiment in which contacts are formed to transistor moats that are self-aligned to moat edges. An example of a fabrication process for the formation of a transistor with such self-aligned moat contacts is as follows:

First, isolation regions 81 are formed using a shallow trench isolation process to define a moat region 80, a gate oxide 82 is grown, and a layer of polysilicon gate material is deposited. A chemical mechanical polishing step is then performed to planarize the wafer surface, forming a gate 83 that is self-aligned to the edges of the moat region 80. This is followed by the deposition of a nitride layer 1005 over the gate 83 and field oxide 81. The nitride 1005 overlying the gate is then patterned to form a contact via. The polysilicon/nitride stack is patterned and nitride sidewalls 84 are formed. An ion implantation is next performed to dope source/drain regions 85, whereafter an oxide is formed over source/drain regions 86.

Self-aligned moat contact formation can then be carried out by etching a contact region in the oxide adjacent to the field oxide and forming a silicide contact 87 therein. A blanket layer of dielectric material is then deposited 88, and vias 89 are etched to allow the silicide contacts 87 to be electrically connected to a subsequently deposited global interconnect layer. It is important to note that this method for self-aligning moat contacts is not limited to use with conductive silicide contacts, but is equally applicable to the formation of other metal or polysilicon contact structures. Also, variations such as including pocket or MDD implants, optionally with multiple side wall layers, can be incorporated.

Alternatively, self-aligned moat contact formation can be carried out by first depositing a global layer of dielectric material 88 and then etching a via 89 extending through the underlying dielectric and oxide layers to expose a region of the moat. A conductive silicide 87 or other contact structure may then be formed in this via.

Alternative Embodiment—Interconnect in the Gate Level

While it is sometimes desirable to have the gate self-aligned to the moat edge, it may also be desirable to selectively have the gate material extend over the field oxide isolating the moat. This can be done with an extra patterned etch of the shallow trench isolation field oxide. An example of a damascene gate fabrication process for this embodiment is as follows:

As illustrated in FIG. 11A, a partially-formed transistor comprised of a moat region 92 defined by a surrounding isolation region 91 created using the aforementioned shallow trench isolation, with nitride 93 over the pad oxide 90 which is over the moat region. As shown in FIG. 11B, a material with etch properties relative to 91 and 93 (e.g. Si, if the isolation region 91 is oxide and the layer covering the pad oxide 90 is nitride 93) is deposited. As shown in FIG. 11C, a gate trench 95 is then patterned and etched into the top layer such that the pattern extends over the field oxide as desired. As in FIG. 11D, resist is deposited and patterned to cover areas where the gate is not to extend over the field, and the field oxide is etched as masked by photoresist 94. The photoresist 94 is then removed, followed by an etch of the pad oxide, formation of the gate oxide, and deposition and planarization of the gate material 97. The resultant gate pattern is self-aligned to the moat edge where desired, and extends into the field region with arbitrary pattern where desired. Subsequent processing can optionally include a local interconnect.

Alternative Embodiment: Split-polysilicon Gate Formation

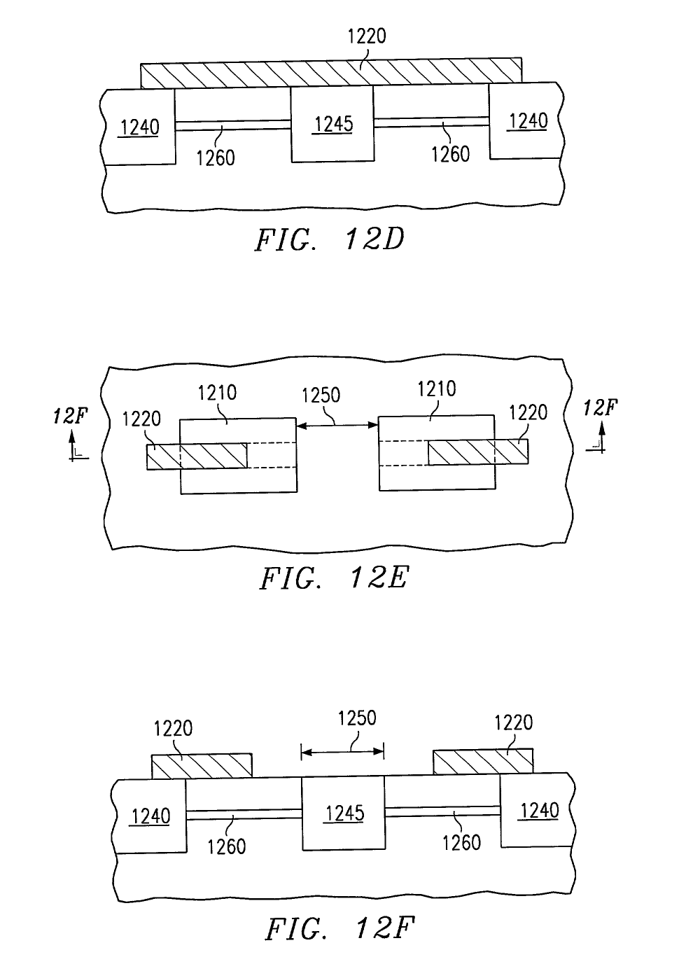

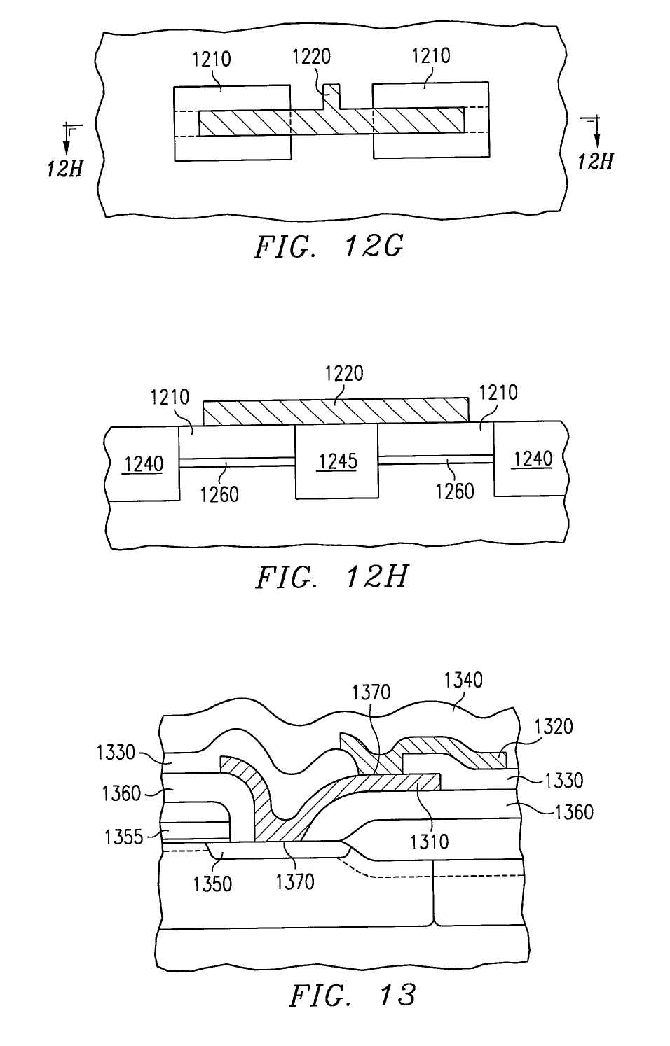

The objective is to have a gate 1210 self-aligned to moat edge and an interconnect 1220 connecting to the gate 1210 in a self-aligned way as depicted in FIGS. 12G and 12H where FIG. 12H is a cross section of FIG. 12G.

Referring to FIGS. 12A and 12B where FIG. 12B is a cross section of FIG. 12A, the first step is to form a shallow trench isolation (STI) 1240, 1245 in a conventional manner. Next remove the moat cover, grow gate oxide 1260, and deposit gate material. Next planarize using chemical mechanical polishing (CMP) for example. Alternatively, deposit the gate 1210 material, etch the trench isolation and fill insulating material.

Next, referring to FIGS. 12C and 12D where FIG. 12D is a cross section of FIG. 12C, deposit interconnect 1220 material. (Note that the channel implants can be done earlier or through the gate 1210 before the interconnect 1220 material. Additionally, if the gate 1210 material is polysilicon, silicide may be formed before depositing the interconnect material.) Next pattern and etch the interconnect 1220 and gate 1210 stack. For example, this could be a tungsten (W) interconnect 1220 with a titanium nitrite (TiN) barrier over the polysilicon gate 1210. To allow for alignment, the interconnect 1220 pattern must extend over the field 1240 at the ends of the gate 1210.

Next, form sidewalls, MDD, pocket implants, S/D implants at this point. Then deposit dielectric and planarize, exposing the top of the interconnect 1220.

Next, referring to FIGS. 12E and 12F where FIG. 12F is a cross section of FIG. 12E, pattern and etch the interconnect 1220 where not wanted, e.g. except over field 1245. Stop on the gate 1210 and field oxide (do not need great selectivity to field oxide). Alternatively, patterning and etching the interconnect 1220 could be done before the sidewalls, MDD, pocket implants, S/D implants are formed.

This allows the minimum moat spacing 1250 as shown in FIGS. 12E and 12F to be less than the minimum gate spacing 23 and gate overlap 24 of the prior art as depicted in FIG. 3.

According to a disclosed class of innovative embodiments, there is provided: An integrated circuit structure, comprising: a plurality of transistors, each having a respective gate coupled to a respective channel region; said gates being parts of a first patterned thin-film layer; said channel regions being formed in semiconductor moat regions which are laterally surrounded by isolation regions; wherein said first patterned thin-film layer lies only within said moat regions, and does not overlie said isolation regions.

According to another disclosed class of innovative embodiments, there is provided: An integrated circuit structure, comprising: a plurality of field-effect transistors, each having a respective gate which is part of a first patterned thin-film conductor layer, coupled to a respective channel region, said channel region being formed in a moat region which is laterally surrounded by isolation regions; wherein no part of said first patterned thin-film layer overlies said isolation regions; a second patterned thin-film conductor layer, which overlies both portions of said isolation regions and also overlies portions of said gates; wherein said second layer contacts said first layer wherever it overlies first layer; wherein at least some portions of said second layer overlie neither said first layer nor said isolation regions.

According to another disclosed class of innovative embodiments, there is provided: An integrated circuit structure, comprising: a plurality of field-effect transistors, each having a respective gate which is part of a first patterned thin-film conductor layer, coupled to a respective channel region, said channel region being formed in a moat region which is laterally surrounded by isolation regions; wherein said first patterned thin-film conductor layer is self-aligned to said isolation region; a second patterned thin-film conductor layer, which overlies both portions of said isolation regions and also overlies portions of said gates; wherein said second layer contacts said first layer wherever it overlies first layer; wherein at least some portions of said second layer overlie neither said first layer nor said isolation regions.

According to another disclosed class of innovative embodiments, there is provided: An integrated circuit structure, comprising: a plurality of field-effect transistors, each having a respective gate which is part of a first patterned thin-film conductor layer, coupled to a respective channel region, said channel region being formed in a moat region which is laterally surrounded by isolation regions; wherein said first patterned thin-film conductor layer selectively extends into said isolation region or is self-aligned to said isolation region.

According to another disclosed class of innovative embodiments, there is provided: An integrated circuit structure, comprising: a plurality of field effect transistors, each having a respective gate which is part of a first patterned thin-film conductor layer, coupled to a respective channel region, said channel region being formed in a moat region which is laterally surrounded by isolation regions; a second patterned thin-film conductor layer, which overlies both portions of said isolation regions and also overlies portions of said gates; wherein said second patterned thin-film conductor layer is self-aligned to said first patterned thin-film conductor layer; wherein at least some portion of said gate region is not overlain by said second patterned thin-film conductor layer.

According to another disclosed class of innovative embodiments, there is provided: A fabrication method, comprising the steps of: (a.) providing a substrate which includes at least one substantially monolithic body of semiconductor material; (b.) depositing a first patterned thin-film layer to function as an etch mask; (c.) etching and filling said substrate to form isolation regions extending vertically above and below the surface of said substrate in regions where said substrate is not overlain by first deposited layer; (d.) forming a second thin-film layer of conductive gate material entirely within moat regions of said substrate laterally defined by said isolation regions, wherein: (i.) said second thin-film layer nowhere substantially overlaps said isolation regions; (ii.) the upper surface of said gate layer is everywhere substantially coplanar with the upper surface of said isolation regions.

According to another disclosed class of innovative embodiments, there is provided: A fabrication method, comprising the steps of: (a.) providing an integrated circuit containing a plurality of field-effect transistors, each having a respective gate, which is part of a first patterned thin-film conductor layer, coupled to a respective channel region formed in a moat region which is laterally surrounded by isolation regions, wherein said gate nowhere overlies said isolation regions; (b.) depositing a second thin-film conformal dielectric layer; (c.) depositing and planarizing a third dielectric layer; and (d.) etching portions of said second and third deposited layers to form windows aligned to one or more lateral edges of said underyling moat regions, wherein the underlying moat region substrate is exposed.

According to another disclosed class of innovative embodiments, there is provided: A fabrication method, comprising the steps of: (a.) providing an integrated circuit containing a plurality of field-effect transistors, each having a respective gate, which is part of a first patterned thin-film conductor layer, coupled to a respective channel region formed in a moat region which is laterally surrounded by isolation regions, wherein said gate nowhere substantially overlies said isolation regions; (b.) depositing a second patterned thin-film layer of conductive material to form local interconnect structures overlying and making contact to portions of said first patterned thin-film conductive layer, wherein said local interconnect structures: (i.) overlie portions of said moat regions; (ii.) overlie portions of said isolation regions; or, (iii.) overlie portions of both said moat regions and said isolation regions.

According to another disclosed class of innovative embodiments, there is provided: A fabrication method, comprising the steps of: (a.) providing an integrated circuit containing a plurality of field-effect transistors, each having a respective gate, which is part of a first patterned thin-film conductor layer, coupled to a respective channel region formed in a moat region which is laterally surrounded by isolation regions, wherein said gate nowhere overlies said isolation regions; (b.) depositing a second patterned thin-film conductor layer with etch characteristics different from said first patterned thin-film conductor layer; (c.) performing a stack etch; and (d.) selectively removing portions of said second patterned thin-film conductor layer.

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

It should also be noted that the number of layers of metallization described above does not implicitly limit any of the claims, which can be applied to processes and structures with more or fewer layers.

Similarly, it will be readily recognized that the described process steps can also be embedded into hybrid process flows, such as BiCMOS or smart-power processes.

What is claimed is:

1. An integrated circuit structure, comprising:
a plurality of transistors, each having a respective gate coupled to a respective channel region;
said gates being parts of a first patterned thin-film layer;
said channel regions being formed in semiconductor moat regions which are laterally surrounded by raised isolation regions;
wherein said first patterned thin-film layer substantially lies only within said moat regions.

2. The integrated circuit structure of claim 1, wherein said first patterned thin-film layer is self-aligned to said isolation regions.

3. The integrated circuit structure of claim 1, wherein said first patterned thin-film layer selectively extends over said isolation region.

4. The integrated circuit of claim 1, further comprising a second patterned thin-film conductor layer, wherein:
said second patterned thin-film conductor layer overlies portions of said first patterned thin-film layer;
at least some portions of said first patterned thin-film layer are not overlain by said second patterned thin-film conductor layer.

5. The integrated circuit of claim 1, further comprising a contact formed directly over said first patterned thin-film layer wherein said contact is electrically connected to said first patterned thin-film layer.

6. The integrated circuit structure of claim 4, wherein said second patterned thin-film conductor layer is self-aligned to said first patterned thin-film conductor layer.

7. The integrated circuit structure of claim 4, wherein said second patterned thin-film layer nowhere overlies said isolation regions.

8. The integrated circuit structure of claim 4, wherein at least some portions of said second patterned thin-film layer do not overlie said first patterned thin-film layer.

9. The integrated circuit structure of claim 4, wherein a contact is formed directly over said second patterned thin-film layer making an electrical connection to said second patterned thin-film layer.

10. An integrated circuit structure, comprising:
a plurality of field-effect transistors, each having a respective gate which is part of a first patterned thin-film conductor layer, coupled to a respective channel region, said channel region being formed in a moat region which is laterally surrounded by isolation regions;
wherein no part of said first patterned thin-film layer substantially overlies said isolation regions;
a second patterned thin-film conductor layer, which overlies both portions of said isolation regions and also overlies portions of said gates;
wherein said second layer contacts said first layer wherever it overlies first layer.

11. The integrated circuit of claim 10, wherein at least some portions of said second layer overlie neither said first layer nor said isolation regions.

12. The integrated circuit of claim 10, wherein at least some portions of said first conductor layer are not overlain by said second conductor layer.

13. The integrated circuit of claim 10, wherein:
some regions of said second patterned thin-film conductor layer make contact with said moat regions at contact locations; and
said contact locations are self-aligned to one or more lateral edges of said moat regions.

14. The integrated circuit of claim 10, further comprising conductive silicides forming ohmic contacts to said moat regions, wherein said ohmic contacts are self-aligned with one or more lateral edges of said moat regions.

15. The integrated circuit of claim 10, wherein:
some regions of said second patterned thin-film conductor layer form contacts with said moat regions at contact locations;
said contact locations are self-aligned to one or more lateral edges of said moat regions; and
portions of said second patterned thin-film conductor layer overlie and are electrically connected to said contacts.

16. A fabrication method, comprising the steps of:
(a.) providing a substrate which includes at least one substantially monolithic body of semiconductor material;
(b.) depositing a first patterned thin-film layer to function as an oxidation mask;
(c.) forming isolation regions extending vertically above and below the surface of said substrate in regions where said substrate is not overlain by first deposited layer;
(d.) forming a second thin-film layer of conductive gate material entirely within channel regions of said substrate laterally defined by said isolation regions, wherein:
(i.) said second thin-film layer nowhere substantially overlaps said isolation regions;
(ii.) the upper surface of said gate layer is everywhere subs tantially coplanar with the upper surface of said isolation regions.

17. A fabrication method, comprising the steps of:
(a.) providing an integrated circuit containing a plurality of field-effect transistors, each having a respective gate, which is part of a first patterned thin-film conductor layer, coupled to a respective channel region formed in a moat region which is laterally surrounded by isolation regions, wherein said gate nowhere overlies said isolation regions;
(b.) depositing a second thin-film conformal dielectric layer;
(c.) depositing and planarizing a third dielectric layer; and
(d.) etching portions of said second and third deposited layers to form windows aligned to one or more lateral edges of said underyling moat regions, wherein the underlying moat region substrate is exposed.

18. The method of claim 17, further comprising the steps of:
(e.) depositing a patterned thin-film layer of conductive material to form:
(i.) contacts with said moat regions that are entirely contained within said window regions of said first deposited layer;
(ii.) local interconnect regions of which portions contact said contacts created in step (e)(i) that:
(1) overlie portions of said channel regions;
(2) overlie portions of said isolation regions; or,
(3) overlie portions of both said isolation regions and said channel regions.

19. The method of claim 17, further comprising the steps of:
(e.) forming conductive silicides within said window regions which contact said moat regions; and
(f.) depositing a patterned thin-film layer of conductive material to form local interconnect regions of which portions contact said conductive silicides created in step (e) that:
(i.) overlie portions of said moat regions; and
(ii.) overlie portions of said isolation regions.

20. A fabrication method, comprising the steps of:
(a.) providing an integrated circuit containing a plurality of field-effect transistors, each having a respective gate, which is part of a first patterned thin-film conductor layer, coupled to a respective channel region formed in a moat region which is laterally surrounded by isolation regions, wherein said gate nowhere substantially overlies said isolation regions;
(b.) depositing a second patterned thin-film layer of conductive material to form local interconnect structures overlying and making contact to portions of said first patterned thin-film conductive layer, wherein said local interconnect structures:
(i.) overlie portions of said moat regions;
(ii.) overlie portions of said isolation regions; or,
(iii.) overlie portions of both said moat regions and said isolation regions.

21. A fabrication method, comprising the steps of:
(a.) providing an integrated circuit containing a plurality of field-effect transistors, each having a respective gate, which is part of a first patterned thin-film conductor layer, coupled to a respective channel region formed in a moat region which is laterally surrounded by isolation regions, wherein said gate nowhere overlies said isolation regions;
(b.) depositing a second patterned thin-film conductor layer with etch characteristics different from said first patterned thin-film conductor layer;
(c.) performing a stack etch; and
(d.) selectively removing portions of said second patterned thin-film conductor layer.
